(19) United States
(12) Patent Application Publication
(10) Pub. No.: US 2015/0187825 A1
(43) Pub. Date: Jul. 2, 2015

(54) Method of Manufacturing Array Substrate of LCD

(71) Applicant: Shenzhen China Star Optoelectronics Technology Co., Ltd., Shenzhen, Guangdong (CN)

(72) Inventors: Xiangyang Xu, Shenzhen (CN); Wei-Min Chang, Shenzhen (CN); Mian Zeng, Shenzhen (CN)

(73) Assignee: Shenzhen China Star Optoelectronics Technology Co., Ltd., Shenzhen, Guangdong (CN)

(21) Appl. No.: 14/346,433

(22) PCT Filed: Jan. 9, 2014
(86) PCT No.: PCT/CN2014/070385

§ 371 Date: Mar. 21, 2014

(30) Foreign Application Priority Data
Dec. 31, 2013 (CN) 201310747724.8

(51) Int. Cl. H01L 27/12; H01L 21/02; H01L 21/3213; H01L 21/027; H01L 29/417; G02F 1/1362; H01L 21/285

(52) U.S. Cl. CPC H01L 27/1288; G02F 1/1362; H01L 27/1259; H01L 21/02271; H01L 21/2855; H01L 21/0272; H01L 29/41733; H01L 21/32133; H01L 21/32134

(57) ABSTRACT

A method for manufacturing an array substrate includes: forming a gate metal film on an bottom substrate, coating the gate metal film with photoresist, exposure imaging and etching the photoresist by a first monotone mask to form patterns with gate scan lines and a gate, and eliminating corresponding photoresist by ashing; continuously depositing a gate insulating layer film, an active layer film and a source-drain metal film on the bottom substrate with the patterns, coating the source-drain metal film with photoresist, exposure imaging the photoresist by a gray-scale mask, and photoresist ashing and etching to form a source, a drain, a channel, and through holes connecting a common electrode lead wire connection area to a gate lead wire connection area; forming a passivation layer on the bottom substrate with the patterns by photoetching process; forming a pixel electrode on the bottom substrate with the patterns by photoetching process. By using the present invention method, it reduces cost of manufacturing the array substrate and improves performance of the array substrate.

### CROSS-REFERENCE TO RELATED APPLICATION

This application claims priority from and the benefit under 35 U.S.C. §119(a) of Chinese Patent Application No. 201310747724.8, filed on Dec. 31, 2013, which is hereby incorporated by reference for all purposes as if fully set forth herein.

### BACKGROUND OF THE INVENTION

1. Field of the Invention

The present invention relates to a manufacturing technology for Thin Film Transistor liquid crystal display (TFT-LCD), more particularly, to a method for manufacturing an array substrate of an LCD.

2. Description of the Prior Art

TFT-LCD is a mainstream of LCDs. A liquid crystal panel of TFT-LCDs in the prior art comprises an array substrate and a color-film substrate. A typical structure of the array substrate comprises a bottom substrate whose data lines and gate lines intersecting widthwise and lengthwise. The data lines and gate lines surround to form pixel units in matrix. Each pixel unit comprises a TFT switch comprising a gate, a source, a drain and an active layer, and comprises a pixel electrode. The gate is connected to the gate lines, the source is connected to the data lines, the source is connected to the pixel electrodes, and the active layer is formed between the source, the drain and the gate. It generally forms common electrode wires on the bottom substrate for inputting common voltages to the common electrode.

To initiate yield enhancement of an array substrate of a TFT-LCD, it usually adds a through hole masking process to a gate lead wire connection area (pad area) after forming the source and the drain. It not only increases manufacturing cost for substrates but also enhances shortcut percentage of source/drain layers attributed by ill evenness.

### SUMMARY OF THE INVENTION

The present invention provides a method for manufacturing an array substrate of an LCD to lower cost and improve performance of the array substrate.

According to the present invention, a method for manufacturing an array substrate, comprises: forming a gate metal film on an bottom substrate, coating the gate metal film with photoresist, exposure imaging and etching the photoresist by a first monotone mask to form patterns with gate scan lines and a gate, and eliminating corresponding photoresist by ashing; continuously depositing a gate insulating layer film, an active layer film and a source-drain metal film on the bottom substrate with the patterns, coating the source-drain metal film with photoresist, exposure imaging the photoresist by a gray-scale mask, and photoresist ashing and etching to form a source, a drain, a channel, and through holes connecting a common electrode lead wire connection area to a gate lead wire connection area, wherein the gray-scale mask is corresponding to at least three different light transmittance; forming a passivation layer on the bottom substrate with the patterns by photoetching process; forming a pixel electrode on the bottom substrate with the patterns by photoetching process.

In one aspect of the present invention, steps for continuously depositing the gate insulation layer film, the active layer and the source-drain metal film on the bottom substrate with the patterns, coating the source-drain metal film with photoresist, exposure imaging photoresist by the gray-scale mask and forms the source, the drain, the channel, and the through holes connecting the common electrode lead wire connection area to the gate lead wire connection area are: continuously depositing a gate insulating layer film, an active layer film and a source-drain metal film on the bottom substrate with the patterns, coating the source-drain metal film with photoresist, exposure imaging photoresist by a gray-scale mask, and forming a first thickness area in a source area and a drain area, forming a second thickness area above a channel area, forming a fourth thickness area above a common electrode lead wire connection area and a gate lead wire connection area, and forming photoresist patterns in a fourth thickness area in other areas through the gray-scale mask; etching the source-drain metal film, the semiconductor layer film and the gate insulation layer film in the fourth thickness area to form a through hole connecting the common electrode lead wire connection area and the gate lead wire connection area and eliminating the photoresist in the third thickness area by ashing; etching the source-drain metal film and the semiconductor layer film in the third thickness area and eliminating the photoresist in the second thickness area by ashing; etching the source-drain metal film in the second thickness area to form a channel and lifting off the rest of the photoresist to form a source and a drain.

In another aspect of the present invention, transmittance of an area on the gray-scale mask corresponding to the first thickness area is a first transmittance, that corresponding to the second thickness area is a second transmittance, that corresponding to the third thickness area is a third transmittance, and that corresponding to the fourth thickness area is a fourth transmittance.

In another aspect of the present invention, the first thickness is greater than the second thickness, the second thickness is greater than the third thickness, the third thickness is greater than the fourth thickness, the first transmittance is lower than the second transmittance, the second transmittance is lower than the third transmittance, and the third transmittance is lower than the fourth transmittance.

In another aspect of the present invention, the fourth thickness is zero, the first transmittance is 0/3, the second transmittance is 1/3, the third transmittance is 2/3, and the transmittance is 3/3.

In another aspect of the present invention, a step for forming the gate metal film on the bottom substrate comprises:

depositing the gate metal film with thickness of 1000 Å˜6000 Å on the bottom substrate by spattering or thermal evaporation.

In another aspect of the present invention, a step for continuously depositing the gate insulation layer film, the active layer and the source-drain metal film on the bottom substrate with the patterns comprises: depositing the gate insulation layer film with thickness of 2000 Å˜5000 Å and the semiconductor layer film with thickness of 1000 Å˜3000 Å on the bottom substrate in sequence by chemical vapor deposition method, and depositing the source-drain metal film with thickness of 1000 Å˜6000 Å by magnetron sputtering or thermal evaporation method.

In another aspect of the present invention, steps for forming a passivation layer on the bottom substrate with the patterns by photoetching process comprise: depositing an insulation protection layer film with thickness of 1000 Å˜3000 Å on the bottom substrate by chemical vapor deposition method; coating the insulation protection layer film with photoresist, and exposure imaging and etching the photoresist by a second monotone mask to form passivation layer patterns and a through hole; and lifting off corresponding photoresist.

In still another aspect of the present invention, steps for forming a pixel electrode on the bottom substrate with the patterns by photoetching process comprise: forming an transparent electrode layer with thickness of 100 Å˜1000 Å on the bottom substrate with the patterns, coating the transparent electrode layer with photoresist, and exposure imaging the photoresist by a third monotone mask to at least form photoresist patterns above a pixel electrode area, the gate lead wire connection area and the data line lead wire connection area; etching by wet etching process and lifting off the photoresist to form pixel electrode patterns.

In yet another aspect of the present invention, a process used in the step for forming the bottom substrate with patterns of a gate scan line and a gate is wet etching process.

According to the present invention, a method for manufacturing an array substrate, comprises: forming a gate metal film on a bottom substrate, coating the gate metal film with photoresist, exposure imaging and etching the photoresist by a first monotone mask to form patterns with a gate scan line and a gate, and eliminating corresponding photoresist by ashing; continuously depositing a gate insulating layer film, an active layer film and a source-drain metal film on the bottom substrate with the patterns, coating the source-drain metal film with photoresist, exposure imaging photoresist by a gray-scale mask, and at least forming a first thickness area in a source area and a drain area, forming a second thickness area above a channel area, forming a fourth thickness area above a common electrode lead wire connection area and a gate lead wire connection area, and forming photoresist patterns in a fourth thickness area in other areas through the gray-scale mask; etching the source-drain metal film, the semiconductor layer film and the gate insulation layer film in the fourth thickness area to form a through hole connecting the common electrode lead wire connection area and the gate lead wire connection area and eliminating the photoresist in the third thickness area by ashing; etching the source-drain metal film and the semiconductor layer film in the third thickness area and eliminating the photoresist in the second thickness area by ashing; etching the source-drain metal film in the second thickness area to form a channel and lifting off the rest of the photoresist to form a source and a drain; forming a passivation layer on the bottom substrate with the patterns by photoetching process; and forming a pixel electrode on the bottom substrate with the patterns by photoetching process.

In one aspect of the present invention, transmittance of an area on the gray-scale mask corresponding to the first thickness area is a first transmittance, that corresponding to the second thickness area is a second transmittance, that corresponding to the third thickness area is a third transmittance, and that corresponding to the fourth thickness area is a fourth transmittance.

In another aspect of the present invention, the first thickness is greater than the second thickness, the second thickness is greater than the third thickness, the third thickness is greater than the fourth thickness, the first transmittance is lower than the second transmittance, the second transmittance is lower than the third transmittance, and the third transmittance is lower than the fourth transmittance.

In another aspect of the present invention, the fourth thickness is zero, the first transmittance is 0/3, the second transmittance is 1/3, the third transmittance is 2/3, and the transmittance is 3/3.

In another aspect of the present invention, a step for forming the gate metal film on the bottom substrate comprises:

depositing the gate metal film with thickness of 1000 Å˜6000 Å on the bottom substrate by spattering or thermal evaporation.

In another aspect of the present invention, steps for continuously depositing the gate insulation layer film, the active layer and the source-drain metal film on the bottom substrate with the patterns comprises:

depositing the gate insulation layer film with thickness of 2000 Å˜5000 Å and the semiconductor layer film with thickness of 1000 Å˜3000 Å on the bottom substrate in sequence by chemical vapor deposition method, and depositing the source-drain metal film with thickness of 1000 Å˜6000 Å by magnetron sputtering or thermal evaporation method.

In another aspect of the present invention, steps for forming a passivation layer on the bottom substrate with the patterns by photoetching process comprise: depositing an insulation protection layer film with thickness of 1000 Å˜3000 Å on the bottom substrate by chemical vapor deposition method;

coating the insulation protection layer film with photoresist, and exposure imaging and etching the photoresist by a second monotone mask to form passivation layer patterns and a through hole; and

lifting off corresponding photoresist.

In still another aspect of the present invention, steps for forming a pixel electrode on the bottom substrate with the patterns by photoetching process comprise:

forming an transparent electrode layer with thickness of 100 Å˜1000 Å on the bottom substrate with the patterns, coating the transparent electrode layer with photoresist, and exposure imaging the photoresist by a third monotone mask to at least form photoresist patterns above a pixel electrode area, the gate lead wire connection area and the data line lead wire connection area; etching by wet etching process and lifting off the photoresist to form pixel electrode patterns.

In yet another aspect of the present invention, a process used in the step for forming the bottom substrate with patterns of a gate scan line and a gate is wet etching process.

The benefit of an embodiment according to the present invention is:

exposure imaging and etching photoresist by a gray-scale mask with various light transmittance on an bottom substrate deposited with gate insulating layer films, active-source films and drain metal films to reduce a number of masks to lower the manufacturing cost of array substrates, and etching gate through holes, etching source-drain layer through holes and channels to achieve excellent capability of a TFT source-drain channel.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a main process diagram that an embodiment of a method for manufacturing an array substrate of an LCD according to the present invention.

FIG. 2 shows a gate forming on the bottom substrate according to the present invention.

FIG. 3 shows a diagram of depositing a gate insulting layer film as shown in FIG. 2.

FIG. 4 shows a diagram of depositing a gate insulting layer, an active layer and a source-drain metal film, and forming a photoresist pattern by using a grey-scale mask as shown in FIG. 2.

FIG. 5 shows a diagram of forming a photoresist pattern.

FIG. 6 shows a diagram of etching a third thickness area shown in FIG. 5.

FIG. 7 shows a diagram of ashing the structure shown in FIG. 6 in the first time.

FIG. 8 shows a diagram of etching a second thickness area shown in FIG. 7.

FIG. 9 shows a diagram of ashing the structure shown in FIG. 8 in the second time.

FIG. 10 shows a diagram of etching a first thickness area shown in FIG. 9.

FIG. 11 shows a diagram of lifting off the rest of the photoresist shown in FIG. 10.

FIG. 12 shows a diagram of forming a passivation layer by photoetching.

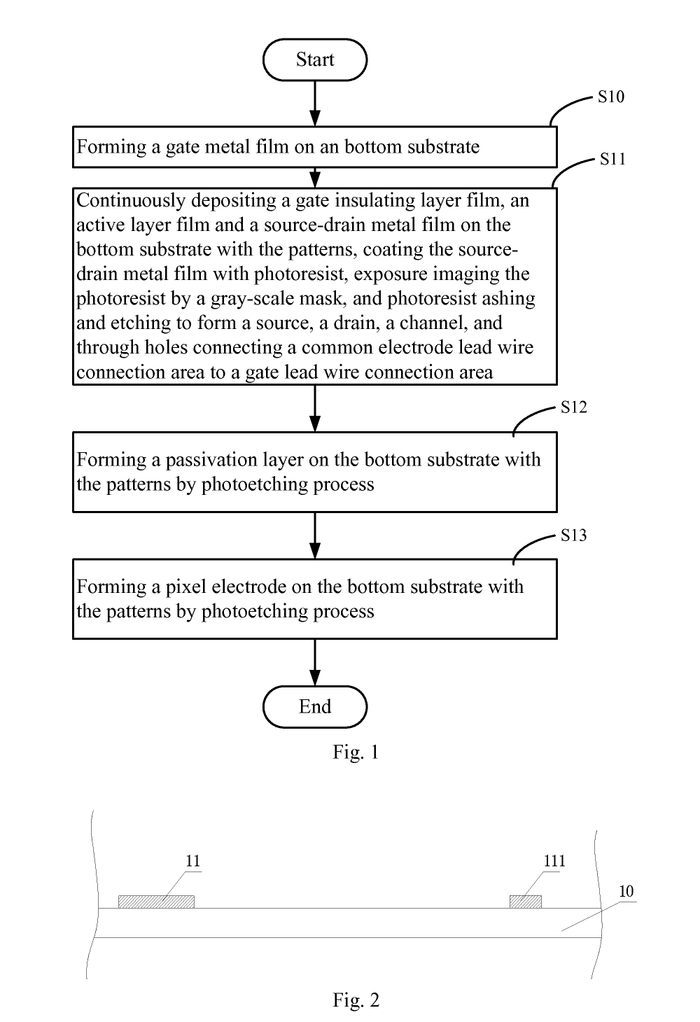

### DETAILED DESCRIPTION OF THE PREFFERED EMBODIMENT

The present invention is described in detail in conjunction with the accompanying drawings and embodiments.

As FIG. 1 shows, FIG. 1 illustrates a main process diagram that an embodiment of a method for manufacturing an array substrate of an LCD according to the present invention. In the embodiment, the method for manufacturing the array substrate of the LCD has the following steps:

Step S10, forming a gate metal film on the bottom substrate 10, coating photoresist on the gate metal film, exposure imaging and etching the photoresist by a first monotone mask to form images with gate scan lines and a gate 11, and eliminating corresponding photoresist by ashing. Specifically, a gate metal film with thickness of 1000 Å˜6000 Å is deposited on a bottom substrate 10 of glasses by spattering or thermal evaporation. The gate metal film is monofilm of Cr, Mo, Al, Cu, Ti or Ta, or complex film made of random sets of Cr, Mo, Al, Cu, Ti and Cu. Etching is able to be wet etching process. Finally, patterns with the gate 11 and gate lead wire connection area 111 (pad area) connecting to the gate 11 are formed in the bottom substrate 10. The detail is shown in FIG. 1.

Step S11, continuously depositing a gate insulating layer film 12, an active layer film 13 and a source-drain metal film 14 on the bottom substrate 10 with the patterns, coating photoresist 3 on the source-drain metal film 14, exposure imaging the photoresist 3 by a gray-scale mask 2, and photoresist ashing process and etching to form a source, a drain, a channel, and through holes connecting common electrode lead wire connection area to gate lead wire connection area.

Specifically, first, it deposits a gate insulating layer film 12 (like SiNx layer) with thickness of 2000 Å˜5000 Å and a semi-conductor layer film 13 (like a-Si layer) with thickness of 1000 Å˜3000 Å on the bottom substrate 10 by chemical vapor deposition method, deposits a source-drain metal film 14 with thickness of 1000 Å˜6000 Å by magnetron sputtering or thermal evaporation method, and coats the photoresist 3 on the source-drain metal film 14.

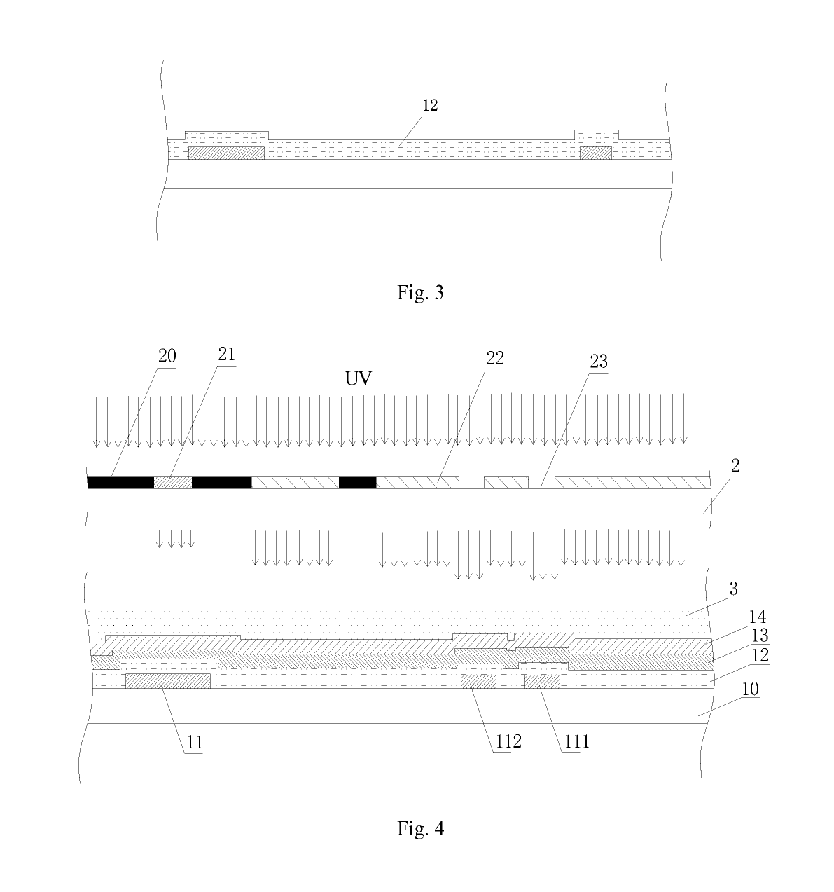

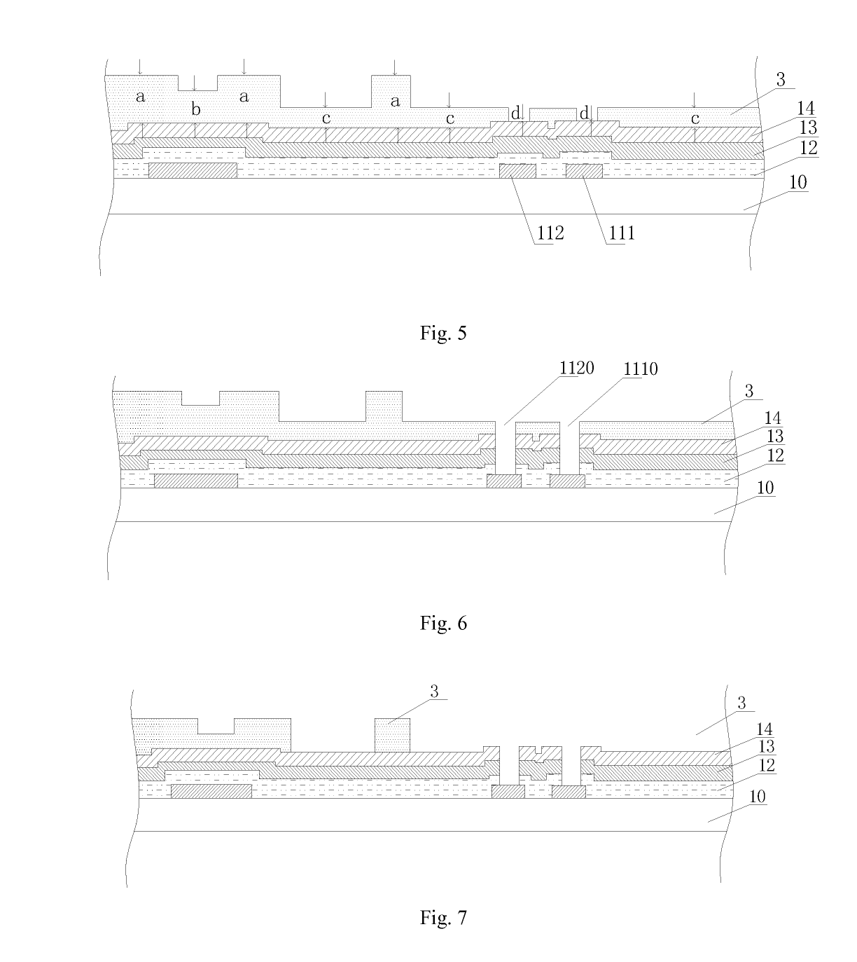

Secondly, it exposure images the photoresist 3 to form photoresist patterns with a gray-scale mask 2, whereas the gray-scale mask 2 comprises areas with at least three different transmittance for forming patterns with different thicknesses on the photoresist 3 under UV exposure. Specifically, through the gray-scale mask 2, a first thickness area (a area) is formed in a source area 141, a drain area 140 and a data line area, a second thickness area (b area) is formed above the channel area, a fourth thickness area (d area) is formed above a common electrode lead wire connection area 112 and a gate lead wire connection area 111, and a third thickness area (c area) is formed in the rest of areas. The first thickness is greater than the second thickness, the second thickness is greater than the third thickness, the third thickness is greater than the fourth thickness, and in an embodiment, the fourth thickness is close or equal to zero. Transmittance of an area on the gray-scale mask 2 corresponding to the first thickness area is a first transmittance 20, that corresponding to the second thickness area is a second transmittance 21, that corresponding to the third thickness area is a third transmittance 22, and that corresponding to the fourth thickness area is a fourth transmittance 23. The first transmittance is lower than the second transmittance, the second transmittance is lower than the third transmittance, and the third transmittance is lower than the fourth transmittance. For instance, in an embodiment, the first transmittance is 0/3, the second transmittance is 1/3, the third transmittance is 2/3, and the transmittance is 3/3. The specific patterns are illustrated in FIG. 4 and FIG. 5.

Thirdly, it etches the part of the third thickness area corresponding to the source-drain metal film, the semi-conductor layer film and the gate insulating layer film to form a through hole 1120 of the common electrode lead wire connection area 112 and a through hole 1110 of the gate lead wire connection area 111, and then ashes to eliminate the photoresist corresponding to the third thickness area to expose a part of the source-drain metal film in the third thickness area, as FIG. 6, and FIG. 7 show;

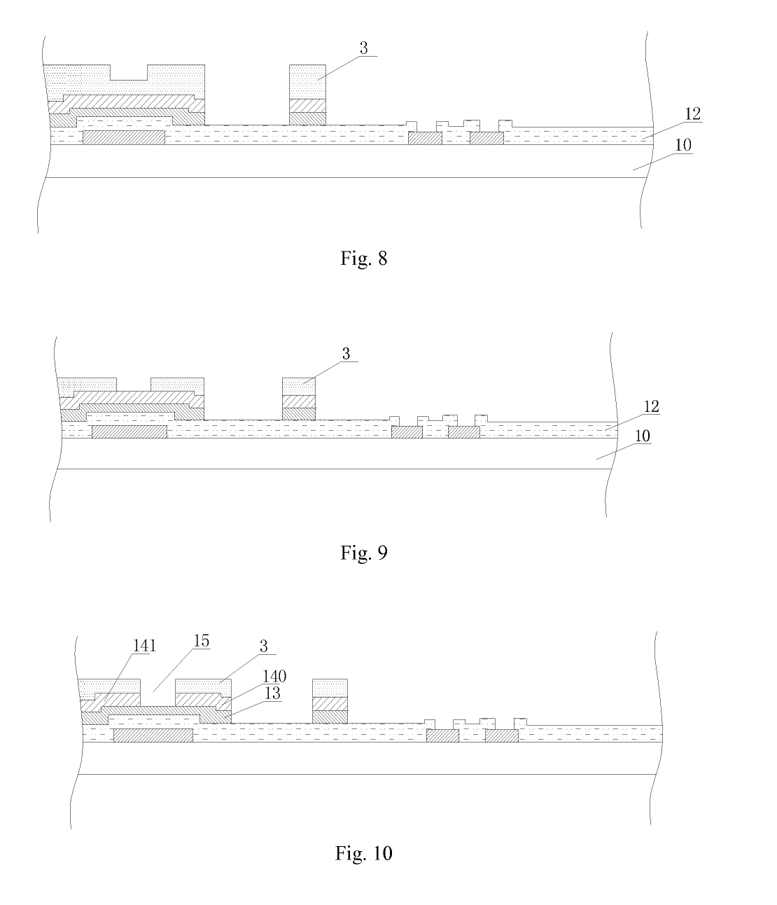

it etches the part of the source-drain metal film and the semi-conductor layer film corresponding to the third thickness area and exposes the source-drain metal film in the second thickness area according to the eliminated photoresist corresponding the second thickness area, as FIG. 8 and FIG. 9 show;

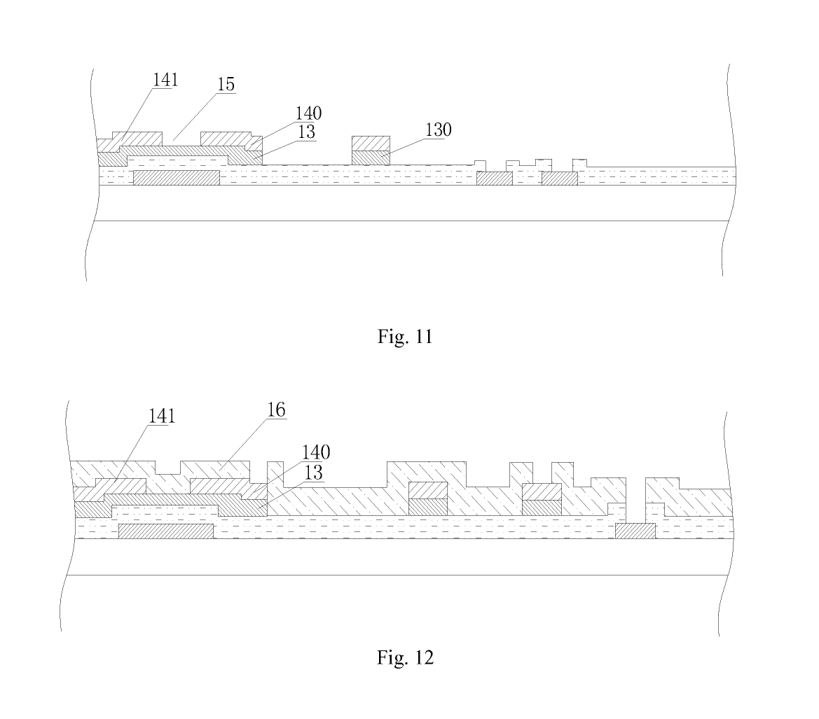

it etches the part of the second thickness area corresponding to the source-drain metal film to form a channel 15 and peels off the rest of the photoresist to from a source area 141, a drain 140 and a data line area 130, as FIG. 10 and FIG. 11 show.

Step S12, forming a passivation layer on the bottom substrate with the above-mentioned patterns by photoetching, specifically comprises:

depositing an insulation protection layer film 16 (like SiNx layer) with thickness of 1000 Å˜3000 Å on the bottom substrate by chemical vapor deposition method, coating the insulation protection layer film 16 with photoresist, and exposure imaging and etching the photoresist by the second monotone mask to form passivation layer patterns and a through hole 160, as FIG. 12 shows.

Step S13, forming pixel electrodes on the bottom substrate with the above-mentioned patterns by photoetching, specifically comprises:

forming an transparent electrode layer (like ITO or IZO layer) with thickness of 100 Å˜1000 Å on the bottom substrate with the above-mentioned patterns, coating the transparent electrode layer with photoresist, and exposure imaging the photoresist by the third monotone mask to at least form photoresist patterns above a pixel electrode area, a gate lead wire connection area and a data line lead wire connection area;

etching by wet etching process and lifting off photoresist to form pixel electrode patterns.

A benefit of the present invention is:

exposure imaging and etching photoresist by a gray-scale mask with various light transmittance on an bottom substrate deposited with gate insulating layer films, active-source films and drain metal films to reduce a number of masks to lower the manufacturing cost of array substrates, and etching gate through holes, source-drain layer through holes and channels to achieve excellent capability of a TFT source-drain channel.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing an array substrate, comprising:
forming a gate metal film on an bottom substrate, coating the gate metal film with photoresist, exposure imaging and etching the photoresist by a first monotone mask to form patterns with gate scan lines and a gate, and eliminating corresponding photoresist by ashing;
continuously depositing a gate insulating layer film, an active layer film and a source-drain metal film on the bottom substrate with the patterns, coating the source-drain metal film with photoresist, exposure imaging the photoresist by a gray-scale mask, and photoresist ashing and etching to form a source, a drain, a channel, and through holes connecting a common electrode lead wire connection area to a gate lead wire connection area, wherein the gray-scale mask is corresponding to at least three different light transmittance;
forming a passivation layer on the bottom substrate with the patterns by photoetching process;
forming a pixel electrode on the bottom substrate with the patterns by photoetching process.

2. The method for manufacturing the array substrate of claim 1, wherein steps for continuously depositing the gate insulation layer film, the active layer and the source-drain metal film on the bottom substrate with the patterns, coating the source-drain metal film with photoresist, exposure imaging photoresist by the gray-scale mask and forms the source, the drain, the channel, and the through holes connecting the common electrode lead wire connection area to the gate lead wire connection area are:
continuously depositing a gate insulating layer film, an active layer film and a source-drain metal film on the bottom substrate with the patterns, coating the source-drain metal film with photoresist, exposure imaging photoresist by a gray-scale mask, and forming a first thickness area in a source area and a drain area, forming a second thickness area above a channel area, forming a fourth thickness area above a common electrode lead wire connection area and a gate lead wire connection area, and forming photoresist patterns in a fourth thickness area in other areas through the gray-scale mask;
etching the source-drain metal film, the semiconductor layer film and the gate insulation layer film in the fourth thickness area to form a through hole connecting the common electrode lead wire connection area and the gate lead wire connection area and eliminating the photoresist in the third thickness area by ashing;
etching the source-drain metal film and the semiconductor layer film in the third thickness area and eliminating the photoresist in the second thickness area by ashing;
etching the source-drain metal film in the second thickness area to form a channel and lifting off the rest of the photoresist to form a source and a drain.

3. The method for manufacturing the array substrate of claim 2, wherein transmittance of an area on the gray-scale mask corresponding to the first thickness area is a first transmittance, that corresponding to the second thickness area is a second transmittance, that corresponding to the third thickness area is a third transmittance, and that corresponding to the fourth thickness area is a fourth transmittance.

4. The method for manufacturing the array substrate of claim 3, wherein the first thickness is greater than the second thickness, the second thickness is greater than the third thickness, the third thickness is greater than the fourth thickness, the first transmittance is lower than the second transmittance, the second transmittance is lower than the third transmittance, and the third transmittance is lower than the fourth transmittance.

5. The method for manufacturing the array substrate of claim 3, wherein the fourth thickness is zero, the first transmittance is 0/3, the second transmittance is 1/3, the third transmittance is 2/3, and the transmittance is 3/3.

6. The method for manufacturing the array substrate of claim 5, wherein a step for forming the gate metal film on the bottom substrate comprises:
depositing the gate metal film with thickness of 1000 Å˜6000 Å on the bottom substrate by spattering or thermal evaporation.

7. The method for manufacturing the array substrate of claim 6, wherein steps for continuously depositing the gate insulation layer film, the active layer and the source-drain metal film on the bottom substrate with the patterns comprises:
depositing the gate insulation layer film with thickness of 2000 Å˜5000 Å and the semiconductor layer film with thickness of 1000 Å˜3000 Å on the bottom substrate in sequence by chemical vapor deposition method, and depositing the source-drain metal film with thickness of 1000 Å˜6000 Å by magnetron sputtering or thermal evaporation method.

8. The method for manufacturing the array substrate of claim 7, wherein steps for forming a passivation layer on the bottom substrate with the patterns by photoetching process comprise: depositing an insulation protection layer film with thickness of 1000 Å˜3000 Å on the bottom substrate by chemical vapor deposition method;
coating the insulation protection layer film with photoresist, and exposure imaging and etching the photoresist by a second monotone mask to form passivation layer patterns and a through hole; and
lifting off corresponding photoresist.

9. The method for manufacturing the array substrate of claim 8, wherein steps for forming a pixel electrode on the bottom substrate with the patterns by photoetching process comprise:
forming an transparent electrode layer with thickness of 100 Å˜1000 Å on the bottom substrate with the patterns, coating the transparent electrode layer with photoresist, and exposure imaging the photoresist by a third monotone mask to at least form photoresist patterns above a pixel electrode area, the gate lead wire connection area and the data line lead wire connection area; etching by wet etching process and lifting off the photoresist to form pixel electrode patterns.

10. The method for manufacturing the array substrate of claim 9, wherein a process used in the step for forming the bottom substrate with patterns of a gate scan line and a gate is wet etching process.

11. A method for manufacturing an array substrate, comprising:
forming a gate metal film on a bottom substrate, coating the gate metal film with photoresist, exposure imaging and etching the photoresist by a first monotone mask to form patterns with a gate scan line and a gate, and eliminating corresponding photoresist by ashing;
continuously depositing a gate insulating layer film, an active layer film and a source-drain metal film on the bottom substrate with the patterns, coating the source-drain metal film with photoresist, exposure imaging photoresist by a gray-scale mask, and at least forming a first thickness area in a source area and a drain area, forming a second thickness area above a channel area, forming a fourth thickness area above a common electrode lead wire connection area and a gate lead wire connection area, and forming photoresist patterns in a fourth thickness area in other areas through the gray-scale mask;
etching the source-drain metal film, the semiconductor layer film and the gate insulation layer film in the fourth thickness area to form a through hole connecting the common electrode lead wire connection area and the gate lead wire connection area and eliminating the photoresist in the third thickness area by ashing;
etching the source-drain metal film and the semiconductor layer film in the third thickness area and eliminating the photoresist in the second thickness area by ashing;
etching the source-drain metal film in the second thickness area to form a channel and lifting off the rest of the photoresist to form a source and a drain;
forming a passivation layer on the bottom substrate with the patterns by photoetching process; and
forming a pixel electrode on the bottom substrate with the patterns by photoetching process.

12. The method for manufacturing the array substrate of claim 11, wherein transmittance of an area on the gray-scale mask corresponding to the first thickness area is a first transmittance, that corresponding to the second thickness area is a second transmittance, that corresponding to the third thickness area is a third transmittance, and that corresponding to the fourth thickness area is a fourth transmittance.

13. The method for manufacturing the array substrate of claim 12, wherein the first thickness is greater than the second thickness, the second thickness is greater than the third thickness, the third thickness is greater than the fourth thickness, the first transmittance is lower than the second transmittance, the second transmittance is lower than the third transmittance, and the third transmittance is lower than the fourth transmittance.

14. The method for manufacturing the array substrate of claim 13, wherein the fourth thickness is zero, the first transmittance is 0/3, the second transmittance is 1/3, the third transmittance is 2/3, and the transmittance is 3/3.

15. The method for manufacturing the array substrate of claim 14, wherein a step for forming the gate metal film on the bottom substrate comprises:
depositing the gate metal film with thickness of 1000 Å˜6000 Å on the bottom substrate by spattering or thermal evaporation.

16. The method for manufacturing the array substrate of claim 15, wherein steps for continuously depositing the gate insulation layer film, the active layer and the source-drain metal film on the bottom substrate with the patterns comprises:
depositing the gate insulation layer film with thickness of 2000 Å˜5000 Å and the semiconductor layer film with thickness of 1000 Å˜3000 Å on the bottom substrate in sequence by chemical vapor deposition method, and depositing the source-drain metal film with thickness of 1000 Å˜6000 Å by magnetron sputtering or thermal evaporation method.

17. The method for manufacturing the array substrate of claim 16, wherein steps for forming a passivation layer on the bottom substrate with the patterns by photoetching process comprise:
depositing an insulation protection layer film with thickness of 1000 Å˜3000 Å on the bottom substrate by chemical vapor deposition method;
coating the insulation protection layer film with photoresist, and exposure imaging and etching the photoresist by a second monotone mask to form passivation layer patterns and a through hole; and
lifting off corresponding photoresist.

18. The method for manufacturing the array substrate of claim 17, wherein steps for forming a pixel electrode on the bottom substrate with the patterns by photoetching process comprise:
forming an transparent electrode layer with thickness of 100 Å˜1000 Å on the bottom substrate with the patterns, coating the transparent electrode layer with photoresist, and exposure imaging the photoresist by a third monotone mask to at least form photoresist patterns above a pixel electrode area, the gate lead wire connection area and the data line lead wire connection area; etching by wet etching process and lifting off the photoresist to form pixel electrode patterns.

19. The method for manufacturing the array substrate of claim 18, wherein a process used in the step for forming the bottom substrate with patterns of a gate scan line and a gate is wet etching process.
